(19) United States
(12) Patent Application Publication
(10) Pub. No.: US 2009/0023290 A1
(43) Pub. Date: Jan. 22, 2009

(54) Planarization method

(75) Inventors: Yuan Tsung Chang, Taipei (TW); Chih Neng Chang, Taipie (TW); Bang Tai Tang, Taipei (TW)

Correspondence Address: BIRCH STEWART KOLASCH & BIRCH, PO BOX 747, FALLS CHURCH, VA, 22040-0747, US

(73) Assignee: NANYA TECHNOLOGY CORPORATION

(21) Appl. No.: 12/068,943

(22) Filed: Feb. 13, 2008

(30) Foreign Application Priority Data
Jul. 20, 2007 (TW) 96126600

(51) Int. Cl. H01L 21/306

(52) U.S. Cl. 438/692; 257/E21.23

(57) ABSTRACT

A planarization method is provided. The method includes the steps of providing a substrate with a first region and a second region, and having a plurality of protrusions of different densities on a surface of said substrate; forming a first dielectric layer on the substrate to fill spaces between the plurality of protrusions; forming a second dielectric layer on the first dielectric layer, wherein the second dielectric layer is formed with a protruding tip having a height higher than heights of the protrusions; and partially removing said first dielectric layer and said second dielectric layer to planarize said first dielectric layer and said second dielectric layer and expose top surfaces of said protrusions.

### CROSS REFERENCE TO RELATED APPLICATIONS

This application claims the right of priority based on Taiwan Patent Application No. 096126600 entitled “Method of Forming Shallow Trench Isolation and Planarization Method Thereof,” filed on Jul. 20, 2007, which is incorporated herein by reference and assigned to the assignee herein.

### FIELD OF THE INVENTION

This invention relates to a planarization method, and more particularly, relates to a chemical mechanical polishing (CMP) process for improving the planarization of a shallow trench isolation.

### BACKGROUND OF THE INVENTION

In the fabrication of the advanced IC chip with nanometer feature size, the shallow trench isolation (STI) technology is a critical isolation technology in isolating devices. However, as the size of the semiconductor device shrinks, the use of chemical mechanical polishing technique to etch back the trench filling (such as silicon oxide) has to meet severe process requirements. The application of reverse mask etch-back (RME) or dummy active areas requires additional processes, such as lithography, etching, and cleaning, and accordingly, the production cost is increased and the alignment of lithography processes is difficult.

Shallow trench isolation (STI) technique offers the advantages of smaller isolation area and better surface planarization. However, the STI process suffers from dishing problems, especially in large trenches, which may cause device leakage in some cases. Currently, a reverse mask and a barrier cap layer are employed as protective layers to avoid dishing during the STI chemical mechanical polishing (CMP) process.

As shown in FIG. 3, in a conventional method, when the chemical mechanical polishing (CMP) process is performed to polish an oxide stack structure, an upper surface of the feature pattern in the array area 32 and an upper surface of the feature pattern in the support area (or the circuit area) 34 need to be in a same plane (i.e., at a same height), such as the barrier layer 36, so that the chemical mechanical polishing can be effectively controlled to stop at a desired level.

For sub-60 nm transistors, a deep trench (DT) self-aligned recessed channel transistor (RCAT) may solve the short channel effect and junction leakage issue without using masking processes. However, after the high-density plasma chemical vapor deposition (HDP CVD) process, the step heights of feature patterns are different due to different pattern densities in the array area and the support area. Thus, the chemical mechanical polishing end-point-detection (CMP EPD) is not easy to control because upper surfaces of the feature patterns in the array area and upper surfaces of the feature patterns in the support area are in different planes. If the filling of the dielectric layer is not enough, the center of the support area will be damaged after the chemical mechanical polishing process.

Therefore, it is desired to provide a planarization method to avoid the dishing problem during the CMP process, so as to achieve a high quality planarization and prevent the leakage current.

### SUMMARY OF THE INVENTION

The present invention provides a planarization method, wherein a polishing mark is formed so that the polishing is performed accurately. For example, a high density plasma chemical vapor deposition process (HDP-CVD) is performed to deposit two dielectric layers sequentially for increasing the filling thickness, and to form the dielectric layer with a protruding tip serving as a polish-end-point detection mark, so that the chemical mechanical polishing can suitably stop on a barrier layer in the array area and in the support area.

According to one aspect of the present invention, a planarization method includes providing a substrate with a first region and a second region, and having a plurality of protrusions of different densities on a surface of said substrate; forming a first dielectric layer on the substrate to fill spaces between the plurality of protrusions; forming a second dielectric layer on the first dielectric layer, wherein the second dielectric layer is formed with a protruding tip having a height higher than heights of the protrusions; and partially removing said first dielectric layer and said second dielectric layer to planarize said first dielectric layer and said second dielectric layer and expose top surfaces of said protrusions.

Some of others aspects of the present invention are described below, and some can be recognized from the specification or the embodiments of the present invention. All aspects of the present invention can be understood and completed by referring to the device and combination in the claim. It should be understood that the general description and the following detail descriptions are for illustration, and not to limit the scope of the present invention.

### BRIEF DESCRIPTION OF THE DRAWINGS

FIG. 1A to FIG. 1C are cross-sectional views showing the process of forming a shallow trench isolation;

FIG. 2 shows a plot of the time-current curve during a chemical mechanical polishing process; and

FIG. 3 is a structure to be polished in the prior art.

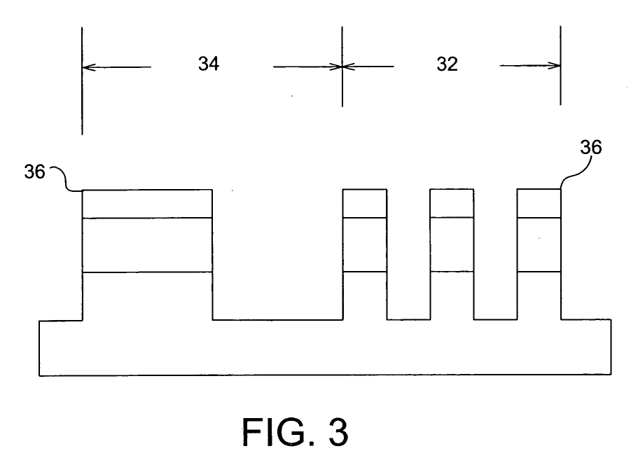

### DETAILED DESCRIPTION OF THE INVENTION

The present invention provides a planarization method, wherein a polishing mark is formed so as to perform a polishing process accurately. Those skilled in the art may be more understood and known well the advantages of the present invention by referring to the following description in conjunction with the accompanying drawings. However, those skilled in the art should understand that the preferred embodiments of the present invention are disclosed herein for purposes of illustration and description, but not to limit the scope of the invention. In particularly, the method of the present invention can be applied to any field that can implement the method of the present invention.

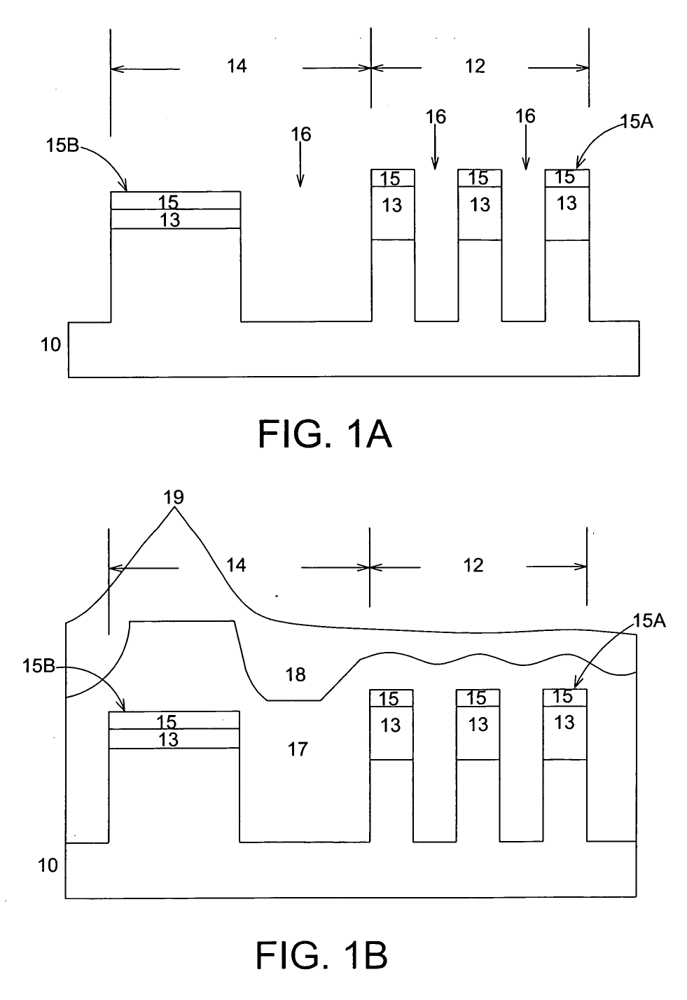

Referring to FIG. 1A, in one embodiment, the present invention provides a planarization method. The method includes providing a substrate 10, which can be a silicon wafer, any suitable semiconductor substrates or multiplayer stack thereof, or any substrate in an appropriate stage of the semiconductor manufacture process. In this embodiment, the substrate 10 may include a hard mask 13 and a barrier layer 15. For example, the hard mask 13 and the barrier layer 15 can be an oxide layer and a nitride layer, respectively. The substrate 10 has a first region 12 and a second region 14, such as an array area and a peripheral circuit area. A plurality of trenches 16 are formed in the first region 12 and the second region 14 of the substrate 10. In this embodiment, the trench density in the first region 12 and the trench density in the second region 14 are different. For example, the trench density in the first region 12 is larger than the trench density in the second region 14. The trenches 16 can be formed after one or more semiconductor processes due to the different pattern densities. In the embodiment, bottoms of the plurality of trenches 16 in the first region 12 and that in the second region 14 are substantially in a same plane, and an top surface of the substrate 10 in the first region 12 and an top surface of the substrate 10 in the second region 14 are substantially in different planes. As shown in FIG. 1A, the top surface 15A in the first region 12 is higher than the top surface 15B in the second region 14. That is, the step height of the trenches 16 in the first region 12 is larger than that of the trench 16 in the second region 14. Please note that though the plurality of trenches 16 with different densities are formed in the substrate 10 as described above, it also indicates that a plurality of protrusions of different densities can be formed on a surface of the substrate, as shown in FIG. 1A.

As shown in FIG. 1B, a first dielectric layer 17 is formed on the substrate 10 in the first region 12 and in the second region 14 to fill the plurality of trenches 16. Then, a second dielectric layer 18 is formed on the first dielectric layer 17, and the second dielectric layer 18 has a protruding tip 19 corresponding to one of the top surfaces of the substrate 10 (such as the top surface 15B). For example, a high density plasma chemical vapor deposition (HDP CVD) process can be preformed to form the first dielectric layer 17 and the second dielectric layer 18, and the protruding tip 19 can be formed by adjusting the deposition rate and the sputter rate. For example, the HDP CVD can be performed at a slower deposition rate to form the first dielectric layer 17 so as to uniformly fill the trenches 16 in the first region 12 and the second region 14 due to the slower deposition rate. Then, the HDP CVD can be performed at a faster deposition rate to form the second dielectric layer 18 with the protruding tip 19 corresponding to the top surface 15B of the substrate 10 due to the faster deposition rate due to the difference in step height of the trenches 16.

In an exemplary embodiment, the HDP CVD is performed to form an oxide layer of about 5500 angstrom at a deposition rate of 124.5 nm/min and a deposition/sputter (D/S) ratio of 10.7, and then to form another oxide layer of about 1500 angstrom at a deposition rate of 545 nm/min and a D/S rate of 4, so that a protruding tip 19 can be formed over the top surface 15B. The first dielectric layer 17 can be formed by the hydrogen (H2) assisted HDP CVD, and the second dielectric layer 18 can be formed by the argon (Ar) assisted HDP CVD. In this embodiment, the D/S ratio of the HDP CVD for forming the first dielectric layer 17 and the second dielectric layer 18 are listed below:

| | Deposition rate | Sputter rate | D/S ratio |
|---|---|---|---|
| first dielectric layer 17 | 124.5 | 12.95 | 10.7 |
| second dielectric layer 18 | 545 | 160 | 4 |

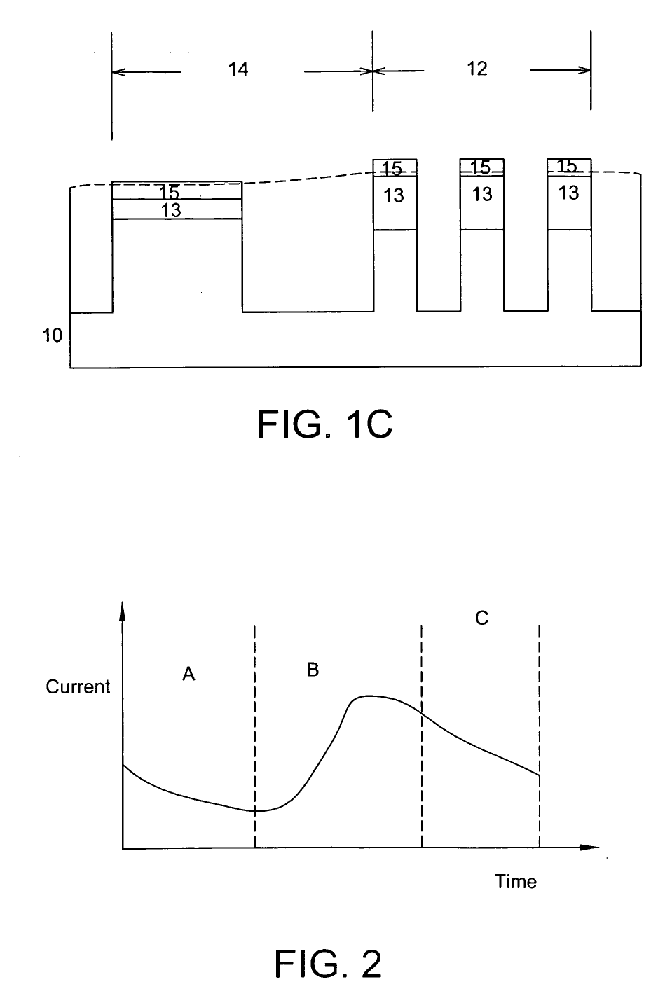

Then, as shown in FIG. 1C, a polishing process is performed by using the protruding tip 19 as a polishing mark to remove the second dielectric layer 18 and the first dielectric layer 17 above the top surfaces of the substrate 10 until the polish-end-point is reached. The dotted line in FIG. 1C shows the final structure after the polishing process. For example, FIG. 2 shows a current change monitored by a polishing end point detector while the chemical mechanical polishing is performed on the protruding tip 19 to determine the polish-end-point. As shown in FIG. 2, the horizontal axis represents the polishing time, and the vertical axis represents the loaded current of the polishing turntable in a chemical mechanical polishing equipment. The “A” region shown in FIG. 2 shows that the loaded current for polishing the protruding tip 19 of the second dielectric layer 18 is smaller at beginning and the variation is small. When the polishing process is performed down to the first dielectric layer 17, the current is larger increased, as the “B” region shown in FIG. 2. When the polishing process is performed down to the barrier layer 15 in the second region 14, the current change is gradually getting stable, as the “C” region shown in FIG. 2. Therefore, from the current change shown in FIG. 2, the polish-end-point can be easily determined. For example, the current change is not obvious when polishing the protruding tip 19 of the second dielectric layer 18, and the current has a significant change when polishing down to the first dielectric layer 17. By monitoring the abrupt change of the current, it can be recognized that the polishing process is about to stop, and therefore, the polish-end-point can be determined. In one embodiment, the polishing process can be immediately stopped when the polishing process enters the “B” region. In another embodiment, the polishing process can be stopped at a certain point after entering the B region, such as after a predetermined time when the abrupt current change is detected. Therefore, the upper surfaces of the structure 10 can be free from damage by over polishing.

Furthermore, the method of forming the shallow trench isolations is S disclosed above to illustrate the planarization method, but those skilled in the art are understood that the planarization method can also be performed on any substrate (such as a substrate having a plurality of protrusions of different densities) by forming a first dielectric layer and a second dielectric layer on the substrate, wherein the second dielectric layer has a protruding tip to determine the polish-end-point, without discussion in any detail herein.

Although specific embodiments have been illustrated and described, it will be obvious to those skilled in the art that various modifications may be made without departing from what is intended to be limited solely by the appended claims.

1. A planarization method comprising:
providing a substrate with a first region and a second region, and having a plurality of protrusions of different densities on a surface of said substrate;
forming a first dielectric layer on said substrate to fill spaces between said plurality of protrusions;
forming a second dielectric layer on said first dielectric layer, wherein said second dielectric layer is formed with a protruding tip having a height higher than heights of said protrusions; and
partially removing said first dielectric layer and said second dielectric layer to planarize said first dielectric layer and said second dielectric layer and expose top surfaces of said protrusions.

2. The planarization method of claim 1, wherein said first dielectric layer and said second dielectric layer removing step comprises chemical mechanical polishing.

3. The planarization method of claim 1, wherein said first dielectric layer forming step comprises forming said first dielectric layer with a first deposition rate, and said second dielectric layer forming step comprises forming said second dielectric layer with a second deposition rate different from said first deposition rate.

4. The planarization method of claim 3, wherein said protruding tip is formed over said second region of said substrate.

5. A method of determining a reference in a base having spaces of different densities to perform chemical mechanical polishing process, comprising:
forming a first dielectric layer on said base to fill in said spaces; and
forming a second dielectric layer on said first dielectric layer, wherein said second dielectric layer has an uppermost protruding tip such that said reference to perform chemical mechanical polishing process is provided.

6. The method of claim 5, wherein said first dielectric layer forming step comprises depositing a dielectric material at a first deposition rate, and said second dielectric layer forming step comprises depositing a dielectric material at a second deposition rate different from said first deposition rate.
